(19) United States
(12) Patent Application Publication
(10) Pub. No.: US 2026/0231808 A1
(43) Pub. Date: Aug. 6, 2026

(54) SEMICONDUCTOR ELEMENT AND SEMICONDUCTOR DEVICE

(71) Applicant: ROHM CO., LTD., Kyoto-shi (JP)

(72) Inventor: Hiroshi OKUMURA, Kyoto-shi (JP)

(21) Appl. No.: 19/457,777

(22) Filed: Jan. 23, 2026

(30) Foreign Application Priority Data
Jan. 31, 2025 (JP) 2025-014530

(51) Int. Cl. H10W 72/20; H10W 90/00; H10W 72/29

(52) U.S. Cl. CPC H10W 72/232; H10W 72/244; H10W 72/248; H10W 90/724; H10W 72/29

(57) ABSTRACT

A semiconductor element comprising a plurality of terminals. The semiconductor element includes a line segment that overlaps with the plurality of terminals. The plurality of terminals are arranged along a first direction of the semiconductor element. The plurality of terminals include a first group, in which centers of gravity are offset to a first side in a second direction perpendicular to the first direction, and a second group, in which centers of gravity are offset to an opposite side from the first group with respect to the line segment. Each of the plurality of terminals has a shape in which a dimension in the second direction is larger than a dimension in the first direction.

### FIELD

The present disclosure relates to a semiconductor element and a semiconductor device.

### BACKGROUND

Semiconductor devices provided with Hall elements are used in various electronic devices such as mobile phones. JP-A-2022-048197 discloses an example of such a semiconductor device provided with a Hall element. The semiconductor device disclosed in JP-A-2022-048197 includes a lead electrically connected to the Hall element, and a resin package covering the Hall element and a part of the lead. Semiconductor devices provided with Hall elements may be used in diversified camera modules. To meet the demand for such diversification, semiconductor devices are expected to be mountable onto various land patterns.

### SUMMARY

An object of the present disclosure is to provide a semiconductor element that has been improved as compared to conventional semiconductor elements, and a semiconductor device including the semiconductor element. In particular, in view of the circumstances described above, an object of the present disclosure is to provide a semiconductor element mountable onto various external substrates with different land patterns.

A semiconductor element provided by a first aspect of the present disclosure includes a plurality of terminals. The semiconductor element includes a line segment that overlaps with the plurality of terminals. The plurality of terminals are arranged along a first direction of the semiconductor element. The plurality of terminals include a first group, in which centers of gravity are offset to a first side in a second direction perpendicular to the first direction, and a second group, in which centers of gravity are offset to an opposite side from the first group with respect to the line segment. Each of the plurality of terminals has a shape in which a dimension in the second direction is larger than a dimension in the first direction.

A semiconductor device provided by a second aspect of the present disclosure includes the semiconductor element provided by the first aspect and an external substrate electrically connected to the semiconductor element. The external substrate includes a plurality of pads electrically connected to the plurality of terminals, respectively. Each of the plurality of pads has a shape different from a shape of each of the plurality of terminals.

Other features and advantages of the present disclosure will be more apparent from the detailed description given below with reference to the accompanying drawings.

### DRAWINGS

FIG. 1 is a plan view showing a semiconductor element according to a first embodiment of the present disclosure.

FIG. 2 is a cross-sectional view along line II–II in FIG. 1.

FIG. 3 is a plan view showing a semiconductor device according to a second embodiment of the present disclosure, with the semiconductor element according to the first embodiment indicated by imaginary lines.

FIG. 4 is a cross-sectional view along line IV–IV in FIG. 3.

FIG. 5 is an enlarged view showing a part corresponding to an area V in FIG. 3.

FIG. 6 shows a part of a semiconductor element according to a variation of the present disclosure, and provides an enlarged view of the area corresponding to FIG. 5.

FIG. 7 shows a part of a semiconductor element according to a variation of the present disclosure, and provides an enlarged view of the area corresponding to FIG. 5.

FIG. 8 shows a part of a semiconductor element according to a variation of the present disclosure, and provides an enlarged view of the area corresponding to FIG. 5.

FIG. 9 shows a part of a semiconductor device according to a variation of the present disclosure, and provides an enlarged view of the area corresponding to FIG. 5.

FIG. 10 shows a part of a semiconductor device according to a variation of the present disclosure, and provides an enlarged view of the area corresponding to FIG. 5.

FIG. 11 shows a part of a semiconductor device according to a variation of the present disclosure, and provides an enlarged view of the area corresponding to FIG. 5.

FIG. 12 is a plan view schematically showing a camera module according to a third embodiment of the present disclosure.

FIG. 13 is an exploded perspective view schematically showing the camera module according to the third embodiment of the present disclosure.

FIG. 14 is a rear view schematically showing a mobile terminal provided with the camera module according to the third embodiment of the present disclosure.

### EMBODIMENTS

The following describes details of the present disclosure with reference to the drawings. In the following description, the same or similar elements are denoted by the same reference numerals and descriptions of such elements will not be repeated.

In the description of the semiconductor element and the semiconductor device according to the present disclosure, the vertical direction in a plan view is referred to as a "first direction x", and the horizontal direction in the plan view as a "second direction y". The direction perpendicular to the first direction x and the second direction y is referred to as a "third direction z". In the present disclosure, the terms such as "up", "down", "right", and "left" are used to indicate the relative positions of elements and components in the drawings, and do not necessarily define the relationship with respect to the direction of gravity.

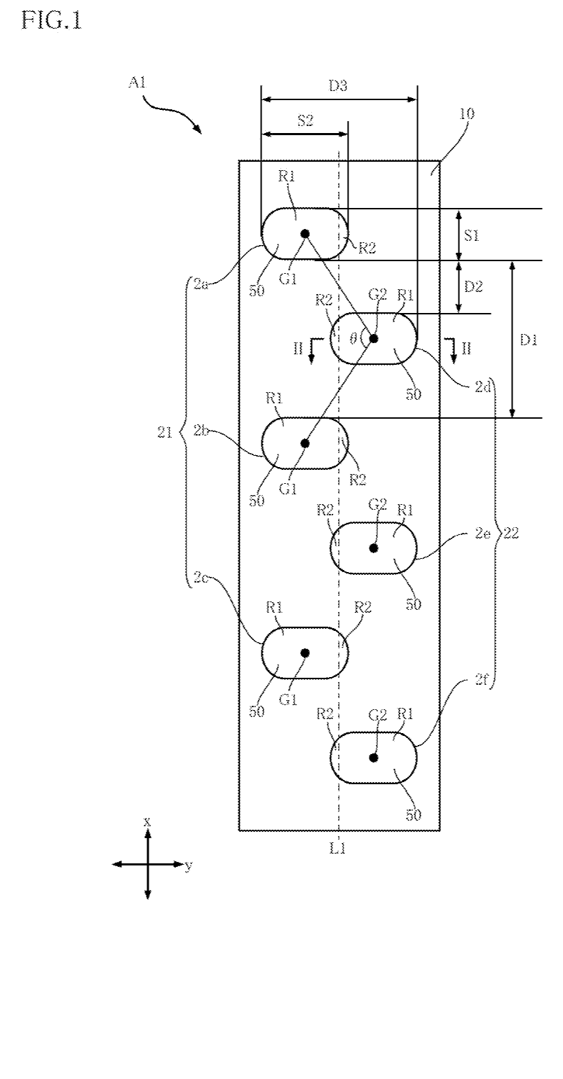

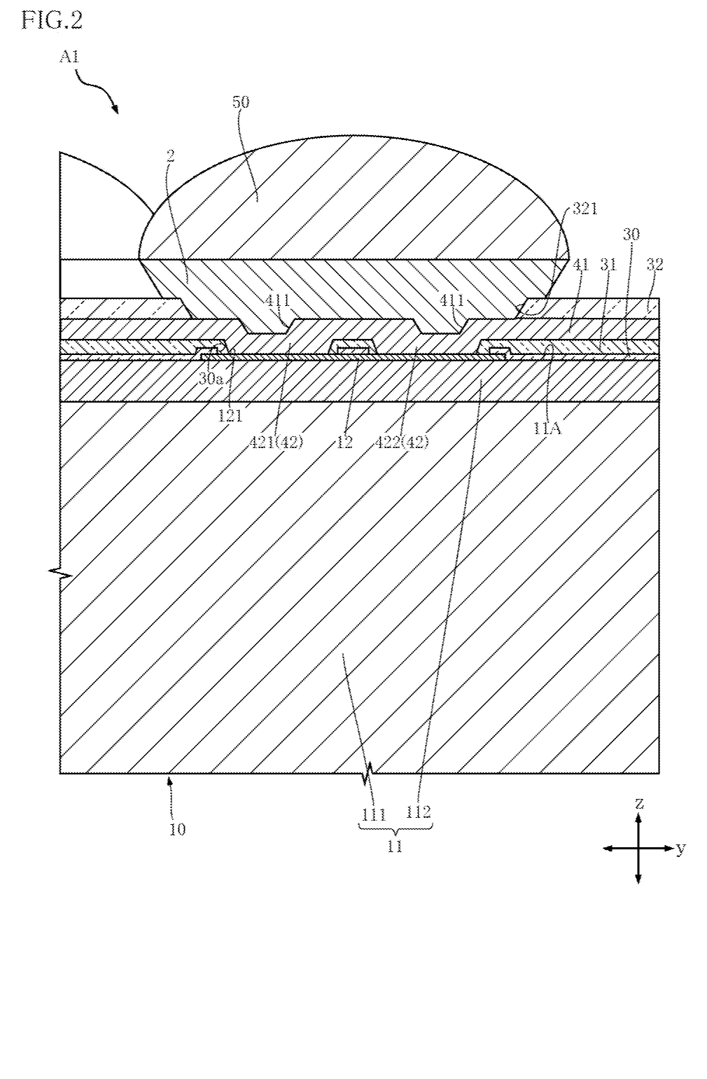

First, a semiconductor element A1 according to a first embodiment of the present disclosure will be described with reference to FIGS. 1 and 2. FIG. 1 is a plan view schematically showing an example of the semiconductor element A1 according to the first embodiment of the present disclosure. As shown in FIG. 1, the semiconductor element A1 is provided in a wafer-level chip scale package (WL-CSP). Alternatively, the semiconductor element A1 may be provided in a fan-out wafer level package (FO-WLP). The semiconductor element A1 may have a rectangular shape wider in the first direction x than in the second direction y as viewed in the third direction z. In the present disclosure, a "rectangular shape" may refer to a quadrilateral in which all four angles are not 90°, a quadrilateral in which all four angles are within ±5° of 90°, or a quadrilateral in which all four corners are rounded. For example, the semiconductor element A1 has a rectangular shape having an aspect ratio of about 2 to 4 as viewed in the third direction z and a short-side length of at least 0.35 mm and at most 0.8 mm. In the present disclosure, the "aspect ratio" means the ratio of the long-side length to the short-side length. The semiconductor element A1 includes a wafer portion 10 and a plurality of terminals 2.

The wafer portion 10 functions as a semiconductor chip incorporating a semiconductor circuit and wiring. The semiconductor chip may include a magnetic sensor, an amplifier, an A/D converter, a PID controller, D/A converter, and an output driver. The wafer portion 10 is made of a semiconductor material. In the present disclosure, the "semiconductor material" may include silicon carbide (SiC), silicon (Si), gallium nitride (GaN), or diamond (C). In the present disclosure, "A is made of a material B" means that A is mainly composed of the material B, and does not mean that A is made of the material B alone.

The semiconductor element A1 includes a line segment L1 overlapping with the terminals 2. FIG. 1 shows the line segment L1 with a single-dot chain line. The line segment L1 divides each of the terminals 2 into two regions, as viewed in the third direction z. The line segment L1 may be located at the center of the semiconductor element A1 in the second direction y, and extends in the first direction x of the semiconductor element A1. The line segment L1 is an imaginary line segment that does not need to physically exist in the semiconductor element A1, and may be defined so as to overlap with the terminals 2. This means that the semiconductor element A1 includes a portion that satisfies a specific condition.

The terminals 2 function as members for electrically connecting the wafer portion 10 to an external substrate (e.g., wiring board). The terminals 2 are made of copper (Cu) or nickel (Ni), for example. The total area of the terminals 2 in plan view may be at least 11% of the area of the semiconductor element A1 in plan view. The number of terminals 2 may be, but not limited to, at least three and at most ten, and is preferably even in order to stabilize the balance of the semiconductor element A1 in the second direction y when the semiconductor element A1 is mounted. The following describes an example in which the terminals 2 include six terminals 2a to 2f as shown in FIG. 1. The six terminals 2a to 2f are referred to as "terminals 2" when distinction is unnecessary. Unless otherwise specified, the six terminals 2a to 2f may have the same or different characteristics. Each of the terminals 2 may be provided with a conductive connecting member 50.

The conductive connecting members 50 function as members for bonding the wafer portion 10 to an external substrate (e.g., wiring board). The periphery of each conductive connecting member 50 coincides with the periphery of the corresponding terminal 2, as viewed in the third direction z. Alternatively, the periphery of each conductive connecting member 50 may be smaller than the periphery of the corresponding terminal 2, as viewed in the third direction z. Each conductive connecting member 50 may be solder that mainly contains tin, or may be silver paste.

Each of the terminals 2 includes at least two different radii of curvature, as viewed in the third direction z. The terminal 2 has a shape having a larger dimension in the second direction y than in the first direction x. In other words, the terminal 2 may have an oval shape. In the present disclosure, the "oval shape" refers to a closed curved shape having a major axis and a minor axis, where the major axis (hereinafter "long axis") is longer than the minor axis (hereinafter "short axis"). The dimension of the terminal 2 along the short axis may be at least 150 μm and at most 300 μm, and the dimension thereof along the long axis may be at least 180 μm and at most 330 μm. In the terminal 2, the ratio of the length of the long axis to the length of the short axis may be in the range of at least 1.05 and at most 1.67. In the illustrated example, the terminal 2 has an elliptical shape whose long axis along the second direction y is longer than the short axis along the first direction x. More specifically, the terminal 2 has an elongated shape composed of a rectangle elongated in the second direction y and two semicircles connected to the respective ends of the rectangle in the second direction y. The terminal 2 has a symmetrical shape with respect to its center of gravity (i.e., the intersection of the long axis and the short axis). In the present disclosure, "the center of gravity of A" refers to the center of gravity of A in three dimensions, or may refer to the geometric center of the shape of a specific surface of A (e.g., a surface of the terminal 2) as seen in one direction. Optionally, the long axes of two adjacent terminals 2 may be parallel to each other.

As viewed in the third direction z, each of the terminals 2 includes a first region R1, in which the center of gravity is located, and a second region R2, in which the center of gravity is not located, with respect to the line segment L1. The ratio of the first region R1 to the second region R2 is at most 98%.

The six terminals 2a to 2f are arranged along the first direction x. In the present disclosure, "a plurality of As are arranged along a direction C" means that each A may be arranged in the direction C while being allowed to be offset in any direction other than the direction C. The six terminals 2a to 2f are arranged in two columns in the second direction y, each column extending in the first direction x. More specifically, the three terminals 2a to 2c are offset in the second direction y relative to the three terminals 2d to 2f. In the illustrated example, the six terminals 2a to 2f are arranged point-symmetrically with respect to the center of the wafer portion 10.

The six terminals 2a to 2f are divided into a first group 21 and a second group 22 with respect to the line segment L1. In the first group 21, centers of gravity G1 are offset to a first side in the second direction y, and in the second group 22, centers of gravity G2 are offset to a second side in the second direction y. In other words, the centers of gravity in the second group 22 are offset to the opposite side from the centers of gravity in the first group 21 with respect to the line segment L1. In the present disclosure, "offset" means that a particular element is displaced from a reference point. In the illustrated example, the centers of gravity G1 coincide with each other in the second direction y, and the centers of gravity G2 also coincide with each other in the second direction y. In the present disclosure, "A and B coincide with each other in a direction C" means that A and B are located at the same position in the direction C while allowing for errors generally recognized as manufacturing tolerances.

In the illustrated example, the first group 21 includes the three terminals 2a to 2c, and the second group 22 includes the three terminals 2d to 2f. The terminal 2b is located between the terminal 2a and the terminal 2c in the first direction x. The terminal 2e is located between the terminal 2d and the terminal 2f in the first direction x. Further, one of the terminals 2d to 2f in the second group 22 is located between two adjacent terminals 2 in the first group 21. In other words, the center of gravity G1 of each of the terminals 2a to 2c in the first group 21 does not overlap with the center of gravity G2 of each of the terminals 2d to 2f in the second group 22 in either the first direction x or the second direction y. Alternatively, each of the terminals 2d and 2e may not be located between any adjacent pair of the terminals 2a to 2c in the first direction x. For example, the three terminals 2a to 2c may be located on the upper left and the three terminals 2d to 2f may be located on the lower right.

FIG. 1 shows a distance D1 between the terminal 2a and the terminal 2b in the first direction x. The distance D1 corresponds to the distance between an end (lower end) of the terminal 2a in the first direction x and an end (upper end) of the terminal 2b in the first direction x. In the present disclosure, "the distance between A and B" refers to the dimension between a specific portion of A and the portion of B closest to (or farthest from) the specific portion of A. The distance between the terminal 2b and the terminal 2c in the first direction x may be the same as the distance D1. In other words, two adjacent terminals 2 in the first group 21 are spaced apart from each other by the distance D1. Similarly, two adjacent terminals 2 in the second group 22 are spaced apart from each other by the distance D1. The distance D1 is at least 200 μm and at most 800 μm, for example. In the present disclosure, "a dimension A is the same as (equal to) a dimension B" may imply the presence of a difference generally recognized as a manufacturing tolerance.

FIG. 1 shows a distance D2 between the terminal 2a and the terminal 2d in the first direction x. The distance D2 corresponds to the distance in the first direction x between an end (lower end) of the terminal 2a in the first direction x and an end (upper end) of the terminal 2d in the first direction x. The distance in the first direction x between any two terminals 2 that are adjacent to each other in the first direction x may be the same as the distance D2. The distance D2 is at least 50 μm and at most 400 μm, for example.

FIG. 1 shows a distance D3 between the terminal 2a and the terminal 2d in the second direction y. The distance D3 corresponds to the distance in the second direction y between an end (left end) of the terminal 2a in the second direction y and an end (right end) of the terminal 2d in the second direction y. The distances between the terminals in the first group 21 and the terminals in the second group 22 in the second direction y may all be the same as the distance D3. The distance D3 is at least 250 μm and at most 650 μm, for example. The distance D3 may be at least 50% relative to the dimension of the semiconductor element A1 in the second direction y.

FIG. 1 shows a dimension S1 of the terminal 2a in the first direction x. The dimension S1 corresponds to the maximum length of the terminal 2a in the first direction x. The dimension of each of the six terminals 2a to 2f in the first direction x may be the same as the dimension S1. The dimension S1 is at least 180 μm and at most 330 μm, for example.

FIG. 1 shows a dimension S2 of the terminal 2a in the second direction y. The dimension S2 corresponds to the maximum length of the terminal 2a in the second direction y. The dimension of each of the six terminals 2a to 2f in the second direction y may be the same as the dimension S2. The dimension S2 is at least 150 μm and at most 300 μm, for example.

FIG. 1 shows an angle θ. The angle θ corresponds to the angle formed by the line segment drawn from the center of gravity G1 of the terminal 2a to the center of gravity G2 of the terminal 2d and the line segment drawn from the center of gravity G1 of the terminal 2b to the center of gravity G2 of the terminal 2d. The angle formed by any three terminals 2 that are arranged along the first direction x may be the same as the angle θ. The angle θ may be at least 60°, for example. This means that three terminals 2 are arranged obliquely relative to each other, as viewed in the third direction z.

FIG. 2 is a cross-sectional view along line II–II in FIG. 1, and shows an example of the internal structure of the wafer portion 10. The following describes an example of one of the terminals 2 and the wafer portion 10 located under the terminal 2. In the illustrated example, the wafer portion 10 includes a body 11, an electrode 12, a first protective film 30, a second protective film 31, a third protective film 32, a rewiring layer 41, a plurality of contact layers 42, and a terminal 2. Note that the internal structure of the wafer portion 10 is not limited to this example. The wafer portion 10 may have different internal structures under the respective terminals 2.

The body 11 includes a semiconductor substrate 111 and a semiconductor layer 112 located on a first side in the third direction z relative to the semiconductor substrate 111. The body 11 has an obverse surface 11A facing the first side in the third direction z. The semiconductor layer 112 includes the obverse surface 11A. The semiconductor substrate 111 is obtained from a wafer. The semiconductor layer 112 includes various semiconductor circuits, such as transistors and diodes, on and near the obverse surface 11A, for example.

The electrode 12 is electrically connected to the semiconductor circuits configured within the semiconductor layer 112. The electrode 12 is located on the first side in the third direction z relative to the body 11. The electrode 12 is in contact with the obverse surface 11A of the body 11. The electrode 12 may contain aluminum (Al), for example.

The electrode 12 has a connection surface 121. The connection surface 121 faces the same side as the obverse surface 11A of the body 11 in the third direction z. A part of the connection surface 121 is covered with the first protective film 30.

The first protective film 30 covers the obverse surface 11A of the body 11 and a part of the electrode 12. The first protective film 30 is a thin film containing silicon dioxide (SiO₂) or silicon nitride (Si₃N₄), or may be a laminate of such thin films.

The first protective film 30 has a first opening 30a. The first opening 30a passes through the first protective film 30 in the third direction z. The connection surface 121 of the electrode 12 is exposed through the first opening 30a. As viewed in the third direction z, the first opening 30a is located inward from the periphery of the connection surface 121.

The second protective film 31 covers a part of the electrode 12 and the first protective film 30. The second protective film 31 is located between the body 11 and the third protective film 32 in the third direction z. The second protective film 31 includes a portion located between the first protective film 30 and the rewiring layer 41. The second protective film 31 further includes a portion accommodated in the first opening 30a of the first protective film 30 and in contact with the first protective film 30 and the rewiring layer 41. The second protective film 31 is an insulator containing an organic compound. More specifically, the second protective film 31 is made of a material containing polyimide, for example.

The third protective film 32 covers the second protective film 31 and the rewiring layer 41. The third protective film 32 is in contact with the terminal 2. The dimension of the third protective film 32 in the third direction z is larger than the dimension of the second protective film 31 in the third direction z. The third protective film 32 has a second opening 321. The second opening 321 passes through the third protective film 32 in the third direction z. The rewiring layer 41 is exposed through the second opening 321. The composition of the third protective film 32 may be the same as or different from the composition of the second protective film 31. Note that the third protective film 32 may not be provided. In this case, it is possible to reduce weight by the amount of the third protective film 32.

The rewiring layer 41 is electrically connected to the electrode 12 via the contact layers 42. The rewiring layer 41 is located between the contact layers 42 and the terminal 2 in the third direction z. The rewiring layer 41 extends in a direction perpendicular to the third direction z (the first direction x and/or the second direction y). The rewiring layer 41 includes a barrier layer in contact with the second protective film 31, a seed layer stacked on the barrier layer, and a plating layer stacked on the seed layer. The barrier layer contains titanium (Ti). Each of the seed layer and the plating layer contains copper (Cu).

The rewiring layer 41 is provided between the second protective film 31 and the third protective film 32. The rewiring layer 41 has a plurality of recesses 411. The recesses 411 are recessed in the third direction z from the side facing the third protective film 32. As viewed in the third direction z, the recesses 411 overlap with the respective contact layers 42. The recesses 411 accommodate a part of the terminal 2.

The contact layers 42 are electrically connected to the electrode 12 and the rewiring layer 41. As a result, the rewiring layer 41 and the contact layers 42 are electrically connected to the electrode 12. The contact layers 42 are located between the electrode 12 and the rewiring layer 41 in the third direction z. Each of the contact layers 42 includes a barrier layer in contact with the electrode 12 and the second protective film 31, a seed layer stacked on the barrier layer, and a plating layer stacked on the seed layer. The barrier layer contains titanium. Each of the seed layer and the plating layer contains copper.

The contact layers 42 include a first contact layer 421 and a second contact layer 422. The first contact layer 421 and the second contact layer 422 are spaced apart from each other in the second direction y. A part of each of the first contact layer 421 and the second contact layer 422 is accommodated in the first opening 30a of the first protective film 30.

The terminal 2 is electrically connected to the rewiring layer 41. As a result, the terminal 2 is electrically connected to the contact layers 42. The terminal 2 is located on the side opposite to the contact layers 42 with respect to the rewiring layer 41 in the third direction z. A part of the terminal 2 is accommodated in the second opening 321 of the third protective film 32. As viewed in the third direction z, the terminal 2 may extend outward beyond the second opening 321. The terminal 2 is exposed from the third protective film 32. More specifically, a part of the terminal 2 protrudes from the third protective film 32 in the third direction z. The terminal 2 contains copper.

As viewed in the third direction z, the terminal 2 overlaps with the first contact layer 421 and the second contact layer 422. As viewed in the third direction z, the area of each of the first contact layer 421 and the second contact layer 422 is smaller than the area of the terminal 2. In addition, as viewed in the third direction z, the terminal 2 overlaps with the entirety of each of the first contact layer 421 and the second contact layer 422. Such a configuration increases the cross-sectional area of the conductive path from the electrode 12 to the terminal 2 in a plane perpendicular to the third direction z. This makes it possible to reduce the resistance value of the conductive path from the electrode 12 to the terminal 2.

The conductive connecting member 50 is electrically connected to the terminal 2. The conductive connecting member 50 is located on the side opposite to the rewiring layer 41 with respect to the terminal 2 in the third direction z. It is preferable that the melting point of the conductive connecting member 50 be lower than the melting point of the terminal 2. The conductive connecting member 50 may have a curved end as viewed in a direction perpendicular to the third direction z.

The semiconductor element A1 has the following advantages.

The semiconductor element A1 has an advantage of being mountable onto various external substrates with different land patterns. The semiconductor element A1 includes the line segment L1 overlapping with the terminals 2. The terminals 2 include the first group 21 in which the centers of gravity G1 are offset to the first side in the second direction y, and the second group 22 in which the centers of gravity G2 are offset to the side opposite to the first group 21 with respect to the line segment L1. Each of the terminals 2 has a shape having a larger dimension in the second direction y than in the first direction x. As viewed in the third direction z, each of the terminals 2 in the semiconductor element A1 has a bonding surface elongated in the second direction y, as compared to a circular bonding surface. As such, the semiconductor element A1 has a higher degree of freedom in mounting.

The semiconductor element A1 includes the terminals 2 arranged in at least two columns extending in the first direction x. Such a configuration is advantageous for mounting the semiconductor element A1 more stably as compared to the configuration in which the terminals 2 are arranged in a single column.

The semiconductor element A1 has an advantage of being easily accommodated in a narrow space. The centers of gravity G1 of the terminals 2a to 2c in the first group 21 coincide with each other in the second direction y, and the centers of gravity G2 of the terminals 2d to 2f in the second group 22 coincide with each other in the second direction y. According to this configuration, the terminals 2 can be formed to be wide in the second direction y while preventing an increase in the dimension of the semiconductor element A1 in the second direction y. In other words, the semiconductor element A1 may have an elongated shape. The elongated shape of the semiconductor element A1 is preferable for arranging the semiconductor element A1 in a narrow space (e.g., the air core of a coil).

Adjacent two of the terminals 2 may include long axes that are parallel to each other. This makes it possible to provide an appropriate spacing between the terminals 2. Such a configuration is advantageous for improving the reliability of the semiconductor element A1.

The terminals 2a to 2c in the first group 21 are arranged alternately with the terminals 2d to 2f in the second group 22. Such a configuration eliminates the need for providing a sufficient spacing between the terminals 2 in the first direction x to prevent short-circuiting therebetween, as compared to the case where all the terminals 2 are arranged adjacent to each other in the first direction x. This is advantageous for reducing the dimension of the semiconductor element A1 in the first direction x. In addition, the wiring for electrically connecting the terminals 2 to the semiconductor chip in the wafer portion 10 can be extended to a greater length. This is because sufficient space is available around each of the terminals 2 in regions extending in the first direction x and the second direction y.

Each of the terminals 2 includes a first region R1, in which the center of gravity G1 or G2 is located, and a second region R2, in which the center of gravity G1 or G2 is not located, with respect to the line segment L1. The ratio of the first region R1 to the second region R2 is at most 98%. Such a configuration allows a sufficient number of terminals 2 to be provided in the second direction y while arranging each of the terminals 2 near the center of the semiconductor element A1 in the second direction y. This is advantageous for further reducing the size of the semiconductor element A1 while further improving stability during mounting.

The following describes other embodiments and variations of the semiconductor element according to the present disclosure. The configurations of the elements in each of the embodiments and the variations can be combined as appropriate as long as the combination does not cause technical contradictions.

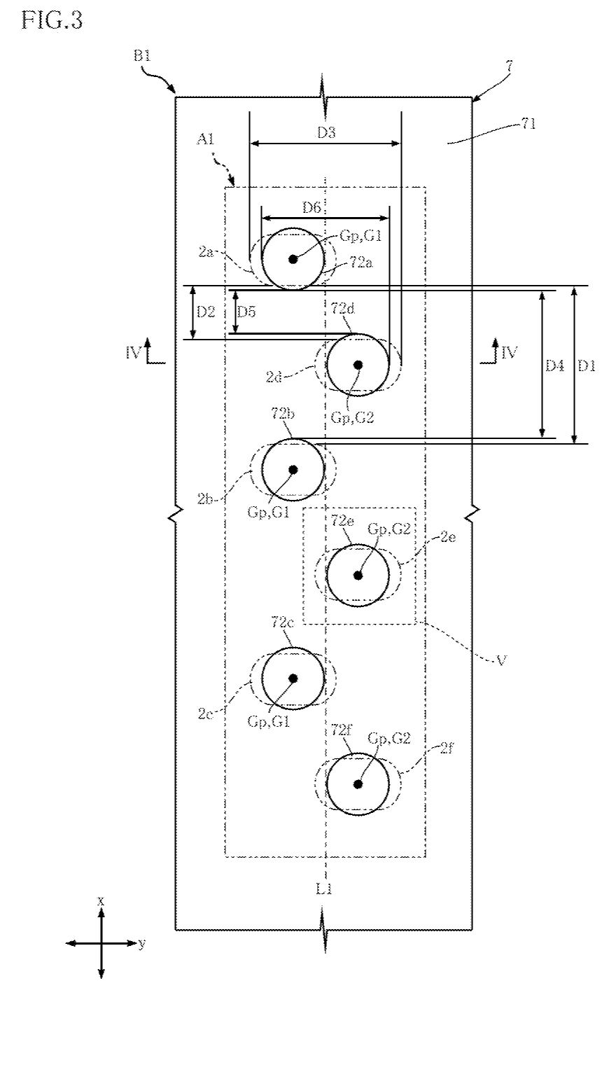

Now, a semiconductor device B1 according to a second embodiment of the present disclosure will be described with reference to FIGS. 3 to 5. FIG. 3 is a plan view schematically showing an example of the semiconductor device B1. FIGS. 3 to 5 also show the line segment L1 with a single-dot chain line. The semiconductor device B1 includes the semiconductor element A1 and an external substrate 7. FIG. 3 shows the wafer portion 10 and the terminals 2 in the semiconductor element A1 with imaginary lines (two-dot chain lines), and the external substrate 7 with solid lines. The semiconductor element A1 is mounted on the external substrate 7. The number of semiconductor elements A1 mounted on the external substrate 7 may be one or more.

The external substrate 7 is a wiring board, for example. More specifically, the external substrate 7 is a wiring board having a so-called multilayer wiring layer made up of a plurality of wiring layers and an insulating layer. The external substrate 7 may be a wiring board larger than the periphery of the semiconductor element A1. For example, the external substrate 7 may be 2 mm longer than the semiconductor element A1 in each of the first direction x and the second direction y. Alternatively, the periphery of the external substrate 7 may be located inside the periphery of the semiconductor element A1, or may coincide with the periphery of the semiconductor element A1.

The external substrate 7 includes a substrate body 71 and a plurality of pads 72. Alternatively, the external substrate 7 may include only the pads 72 serving as leads. As another alternative, the external substrate 7 may include an external terminal located on the side opposite to the pads 72 with respect to the substrate body 71 in the third direction z. The substrate body 71 includes an insulator. Each of the pads 72 includes metal (e.g., Cu).

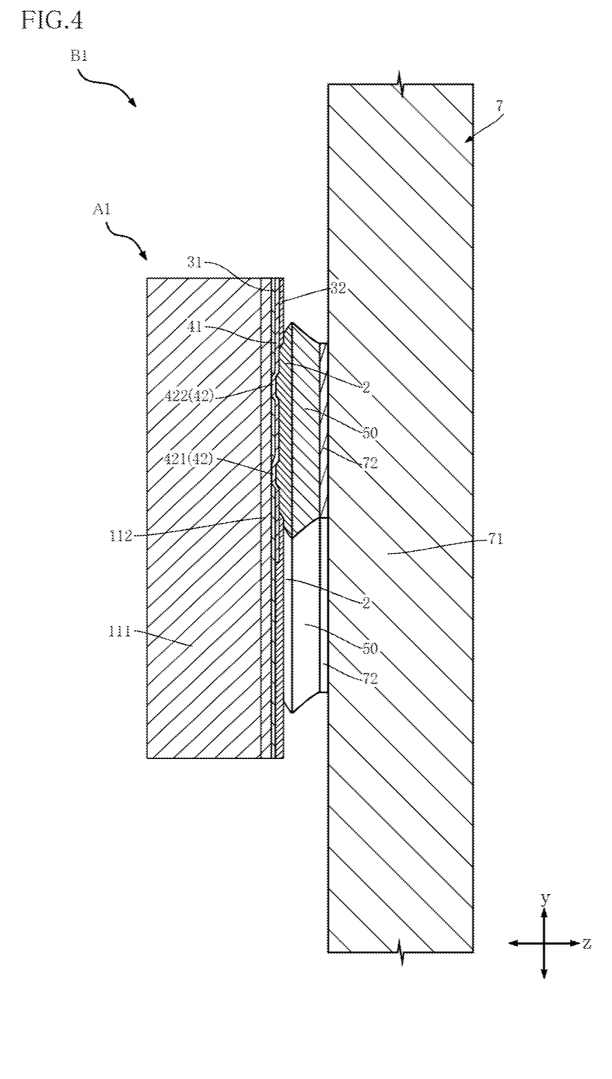

FIG. 4 is a cross-sectional view along line IV–IV in FIG. 3, and shows an example of the internal structure of the semiconductor device B1. In the illustrated example, each of the conductive connecting members 50 is melted and bonded to a pad 72. The conductive connecting member 50 covers the entirety of the surface of the pad 72 facing in the third direction z. Unlike the illustrated example, the conductive connecting member 50 may cover a part of the surface of the pad 72 facing in the third direction z, and may leak out of the pad 72. The conductive connecting member 50 is located between the terminal 2 and the pad 72 in the third direction z. The semiconductor element A1 is spaced apart from the external terminal 7 in the third direction z by the combined thicknesses of a part of the terminal 2 and the conductive connecting member 50 in a molten state. Unlike the illustrated example, the semiconductor element A1 may be covered with a sealing resin such as an underfill. The sealing resin may cover the periphery of each of the plurality of terminals 2 and fill the space between adjacent pairs of the terminals 2. Such a configuration can strengthen the adhesive force between the semiconductor element A1 and the external substrate 7 and make the semiconductor device B1 less susceptible to external influences.

As shown in FIGS. 3 and 4, the pads 72 are bonded to the respective conductive connecting members 50 of the semiconductor element A1. In other words, the substrate body 71 is electrically connected to the semiconductor element A1 via the terminals 2. The number of pads 72 is not particularly limited, but may be the same as the number of terminals 2. The following describes an example in which the pads 72 include six pads 72a to 72f as shown in FIG. 3.

The six pads 72a to 72f are provided at positions corresponding to the six terminals 2a to 2f. In the present disclosure, each of the "corresponding positions" refers to the position overlapping with at least a part of a terminal 2 as viewed in the third direction z. In other words, in the illustrated example, the six pads 72a to 72f are arranged in two columns in the second direction y, each column extending along the first direction x. Further, it is preferable that centers of gravity Gp of the pads 72a to 72f be located near the respective centers of gravity G1 and G2 of the terminals 2a to 2f. In the present embodiment, the center of gravity Gp of each of the six pads 72a to 72f overlaps with a corresponding one of the centers of gravity G1 and G2 of the six terminals 2a to 2f. In the present disclosure, "A overlaps with B as viewed in a certain direction" includes "A overlaps with the entirety of B" and "A overlaps with a part of B". In other words, the angle formed by three pads 72 that are arranged along the second direction y may be the same as the angle θ.

FIG. 3 shows a distance D4 between the pad 72a and the pad 72b in the first direction x. The distance D4 corresponds to the minimum distance between the pad 72a and the pad 72b in the first direction x. Each of the distance between the pad 72b and the pad 72c, the distance between the pad 72d and the pad 72e, and the distance between the pad 72e and the pad 72f may be the same as the distance D4. In other words, the two pads 72 facing each other in the first direction x may be spaced apart from each other by the distance D4. The distance D4 is at least 200 μm and at most 800 μm, for example. The distance D4 is shorter than the distance D1.

FIG. 3 shows a distance D5 between the pad 72a and the pad 72d in the first direction x. The distance D5 corresponds to the minimum distance between the pad 72a and the pad 72d in the first direction x. The distance in the first direction x between any two pads 72 that are adjacent to each other in the first direction x may be the same as the distance D5. The distance D5 is at least 50 μm and at most 400 μm, for example. The distance D5 is shorter than the distance D2.

FIG. 3 shows a distance D6 between the pad 72a and the pad 72d in the second direction y. The distance D6 corresponds to the maximum distance between the pad 72a and the pad 72d in the second direction y. The distance in the second direction y between any two pads 72 that are adjacent to each other in first direction x may be the same as the distance D6. The distance D6 is at least 250 μm and at most 650 μm, for example. The distance D6 is shorter than the distance D3.

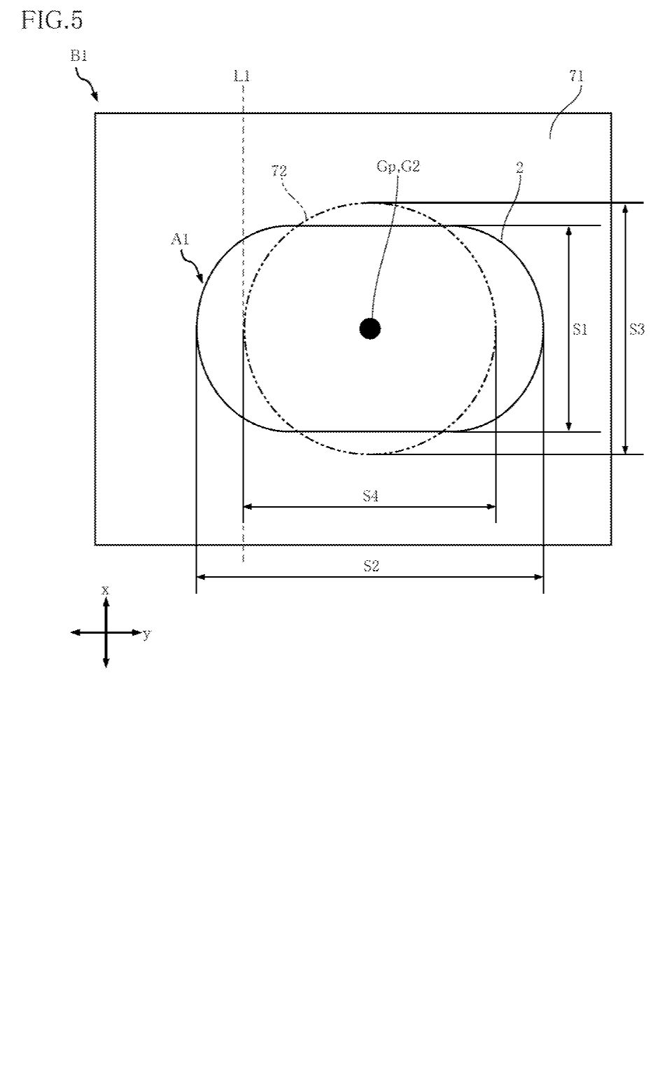

FIG. 5 is an enlarged view of an area V in FIG. 3, and shows a terminal 2 and a pad 72. FIG. 5 shows the semiconductor element A1 (the terminal 2) with a solid line, and the external substrate 7 (the pad 72) with an imaginary line (two-dot chain line). The following describes the configuration of each pad 72 with reference to FIG. 5. The terminals 2a to 2f may have the same or different characteristics, and the pads 72a to 72f may similarly have the same or different characteristics.

The pad 72 has a circular shape as viewed in the third direction z. In the present embodiment, the pad 72 is in contact with the line segment L1. The pad 72 may have a shape in which a dimension S3 in the first direction x is equal to a dimension S4 in the second direction y. Each of the dimension S3 and the dimension S4 is at least 150 μm and at most 350 μm. The dimension S3 of the pad 72 is larger than the dimension S1 of the terminal 2. The dimension S4 of the pad 72 is smaller than the dimension S2 of the terminal 2. The pad 72 may have a shape different from the illustrated example. For example, the pad 72 may have a square shape as viewed in the third direction z.

The semiconductor device B1 has the following advantages.

The semiconductor device B1 may be implemented in various forms. The semiconductor device B1 includes the semiconductor element A1, and the external substrate 7 electrically connected to the semiconductor element A1. The external substrate 7 includes the pads 72 electrically connected to the respective terminals 2. Each pad 72 has a shape different from the shape of each terminal 2. As described above, each of the terminals 2 has a shape having a larger dimension in the second direction y than in the first direction x. Thus, the semiconductor device B1 has the advantage that the semiconductor element A1 is reliably mounted onto the external substrate 7 even if the pads 72 are slightly offset from the terminals 2.

The semiconductor device B1 has improved reliability. The distance D2 between two adjacent terminals 2 in the first direction x may be greater than the distance D5 between two adjacent pads 72 in the first direction x. Such a configuration can reduce bridging between the conductive connecting members 50 in a molten state when the semiconductor element A1 is bonded to the external substrate 7.

The dimension S1 of each terminal 2 in the first direction x may be smaller than the dimension S3 of each pad 72 in the first direction x. Such a configuration can also reduce bridging between the conductive connecting members 50 in a molten state when the semiconductor element A1 is bonded to the external substrate 7.

Each terminal 2 has a shape having a larger dimension in the second direction y than in the first direction x. On the other hand, each pad 72 has a shape in which the dimension in the first direction x is equal to the dimension in the second direction y. More specifically, each terminal 2 has an elliptical shape while each pad 72 has a circular shape. Even when elements having such different shapes are bonded together, the semiconductor element A1 can be reliably mounted onto the external substrate 7 since the terminals 2 are arranged in correspondence with the pads 72. In other words, such a configuration improves reliability.

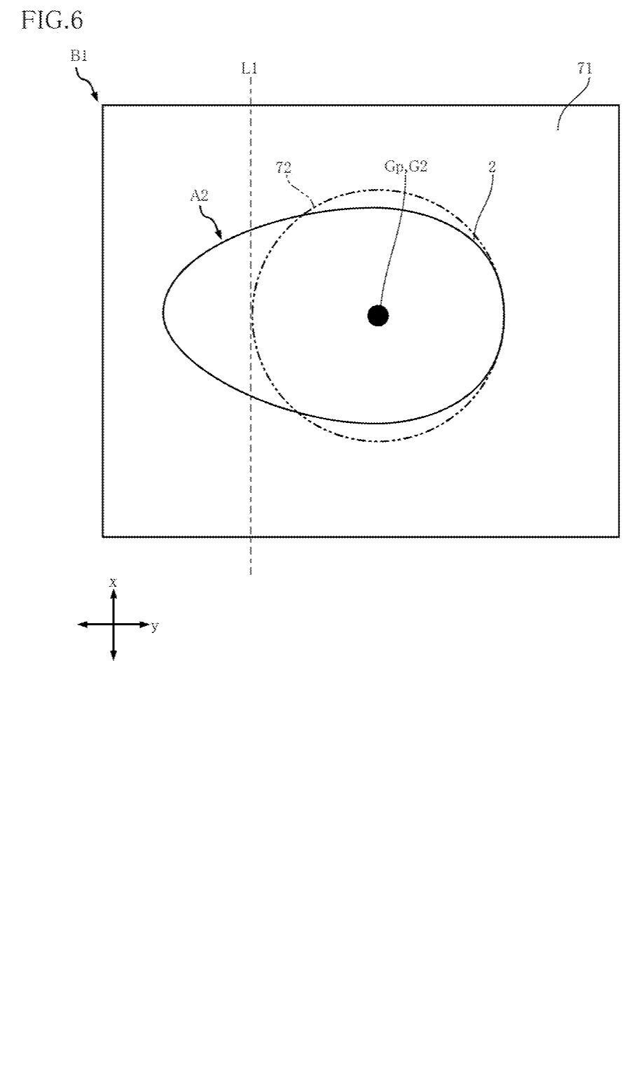

The following describes semiconductor elements A2 to A4 according to variations of the first embodiment, with reference to FIGS. 6 to 8. For convenience of understanding, FIGS. 6 to 8 show the semiconductor elements A2 to A4 according to the variations in a state where each of the semiconductor elements A2 to A4 is mounted on an external substrate 7 to constitute a semiconductor device B1. Each of the semiconductor elements A2 to A4 is different from the semiconductor element A1 in the shape of each terminal 2 as viewed in the third direction z.

FIG. 6 shows a semiconductor element A2 according to a variation of the first embodiment. The semiconductor element A2 includes a terminal 2 having a teardrop shape. In the present disclosure, the "teardrop shape" refers to a shape in which a rounded portion and a tapered tip portion are smoothly connected to each other. The "teardrop shape" is not limited to a symmetrical shape. The terminal 2 of the semiconductor element A2 may have a teardrop shape including a portion tapered toward the center (i.e., the line segment L1) in the second direction y. In the present disclosure, "A includes C tapered toward B" means that the cross-sectional area of C decreases as it approaches B. Further, the center of gravity G2 of the terminal 2 may coincide with the center of gravity Gp of the pad 72.

With such a configuration, it is possible to provide the terminal 2 such that a sufficient area thereof is located at a position corresponding to the pad 72, while reducing the amount of the conductive connecting member 50 that protrudes from the pad 72. Thus, the semiconductor element A2 can reduce bridging between a plurality of conductive connecting members 50 while strengthening the bonding with the external substrate 7.

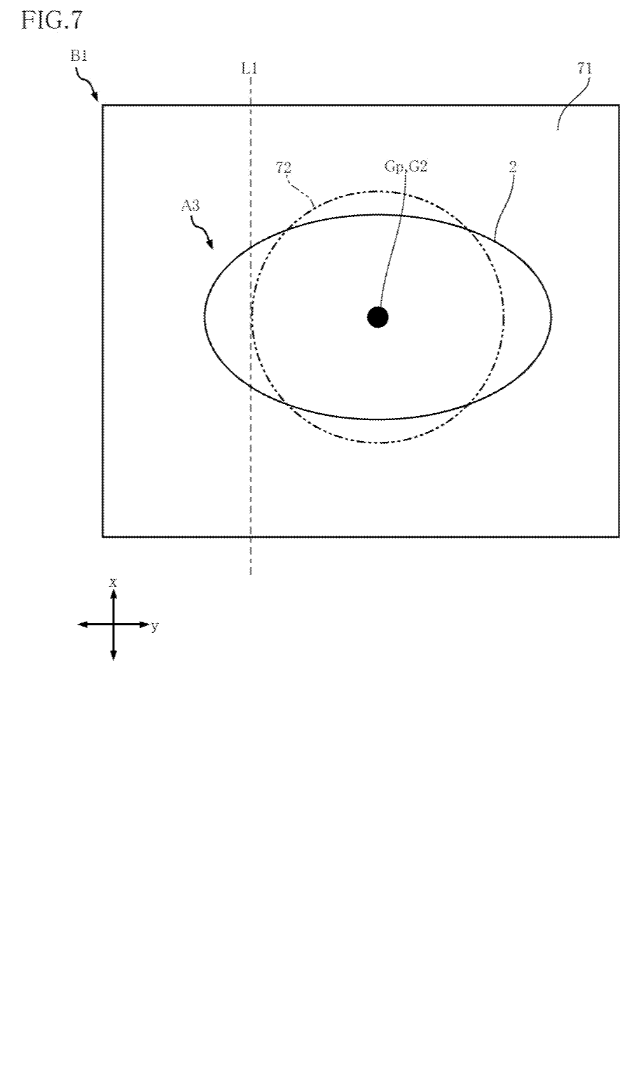

FIG. 7 shows a semiconductor element A3 according to a variation of the first embodiment. The semiconductor element A3 includes a terminal 2 having an elliptical shape. The terminal 2 has a long axis along the second direction y. The terminal 2 has a symmetrical shape along the long axis. Further, the center of gravity G2 of the terminal 2 may coincide with the center of gravity Gp of the pad 72.

With such a configuration, the terminal 2 can be formed to have a substantially rounded symmetrical shape. Such a shape is advantageous for evenly dispersing stress. Thus, the semiconductor element A3 has an advantage of high durability against thermal expansion of the terminal 2. In addition, such a shape is advantageous for uniformizing the flow of the current through the terminal 2 and reducing resistance.

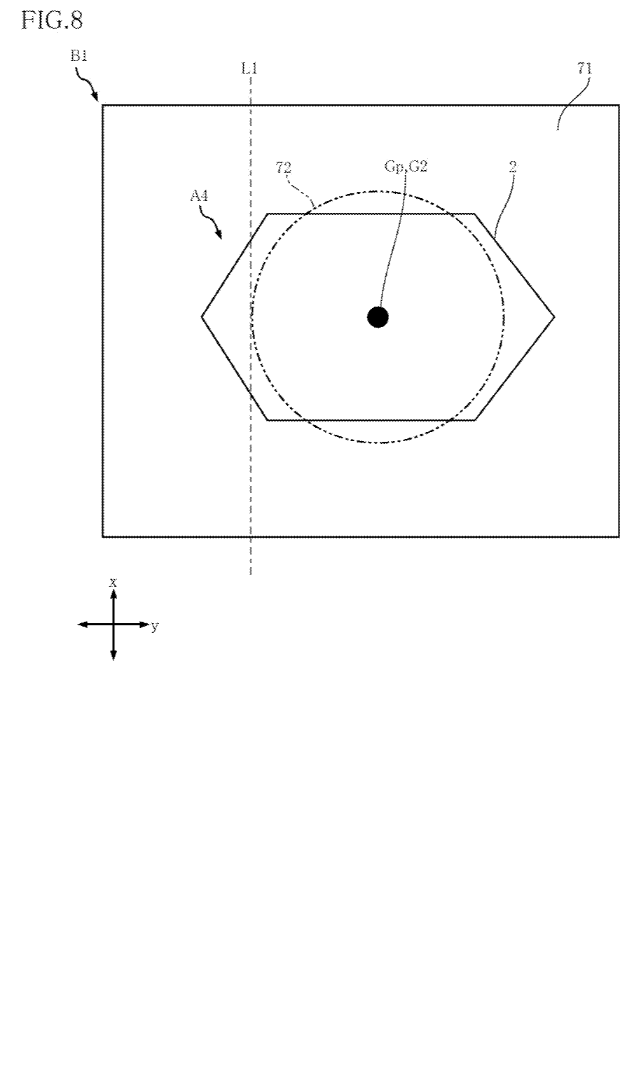

FIG. 8 shows a semiconductor element A4 according to a variation of the first embodiment. The semiconductor element A4 includes a terminal 2 having a hexagonal shape. The terminal 2 has a long axis along the second direction y. The terminal 2 has a symmetrical shape along the long axis. Further, the center of gravity G2 of the terminal 2 may coincide with the center of gravity Gp of the pad 72.

With such a configuration, the terminal 2 can be formed into a shape having many edges. Such a shape facilitates concentrating force to a particular location, thereby improving the stability of bonding between the terminal 2 and the pad 72. As can be understood from such an effect, the terminal 2 may have a polygonal shape other than a hexagonal shape.

As can be understood from the above descriptions, the terminal 2 may take various shapes within a range that does not give rise to technical inconsistency with the present disclosure. Such a shape can be achieved by pouring a metallic raw material into a mold or forming a micro pattern on a surface for guiding a polygonal shape. The conductive connecting member 50 can be formed into a shape corresponding to the shape of the terminal 2 by using a solder preform, for example.

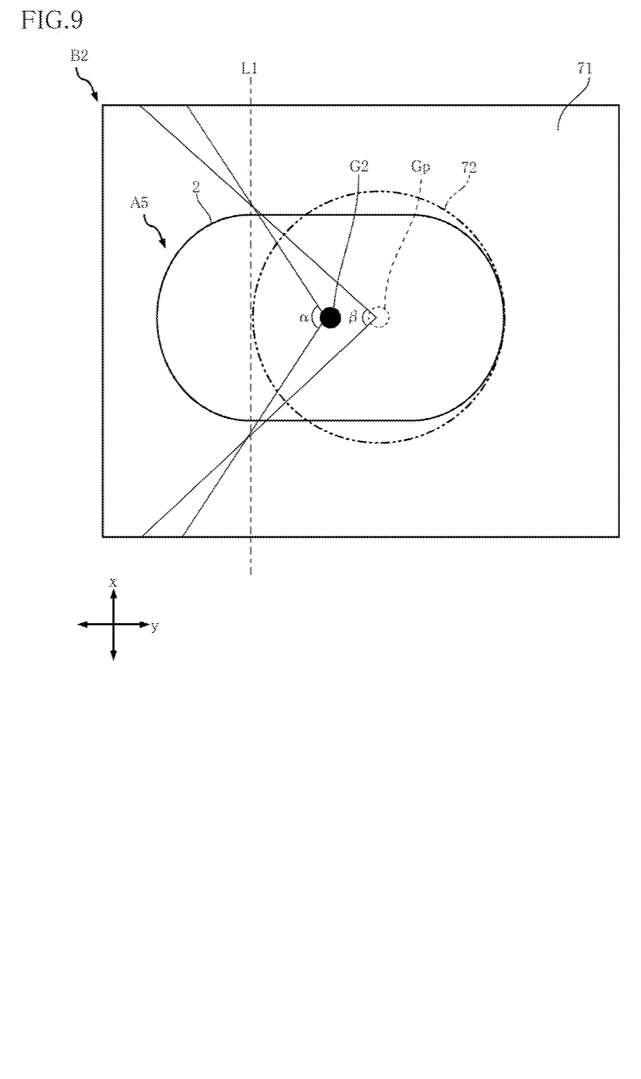

The following describes semiconductor devices B2 to B4 according to variations of the second embodiment, with reference to FIGS. 9 to 11. For convenience of understanding, each of FIGS. 9 to 11 shows a state in which a semiconductor element A1 is mounted. The semiconductor devices B2 to B4 may include the terminal 2 of any one of more of the semiconductor elements A2 to A4. Each of the semiconductor devices B2 and B3 is different from the semiconductor device B1 in the relative position of a terminal 2 and a pad 72. The semiconductor device B4 is different from the semiconductor device B1 in the size of a pad 72.

FIG. 9 shows a semiconductor device B2 according to a variation of the second embodiment. In the semiconductor device B2, the center of gravity G2 of the terminal 2 does not coincide with the center of gravity Gp of the pad 72, as viewed in the third direction z. More specifically, the center of gravity G2 of the terminal 2 is offset from the center of gravity Gp of the pad 72 toward the line segment L1 (the left side in FIG. 9). Thus, the terminal 2 in the present variation has a larger proportion of the second region R2 than each of the terminals 2 in the semiconductor element A1.

FIG. 9 shows angles α and β. The angle α corresponds to the angle formed by the line segments connecting the centers of gravity of three terminals 2. The angle β corresponds to the angle formed by the line segments connecting the centers of gravity of three pads 72. The distance between an adjacent pair among the three terminals 2 is smaller than the distance between a corresponding adjacent pair among the three pads 72. Thus, the angle α is larger than the angle β.

According to such a configuration, it is possible to concentrate stress on a part of the bonding surface of each terminal 2, rather than uniformly applying stress to the entirety of the bonding surface. In other words, the semiconductor device B2 has an advantage of reducing the risk of damaging the terminals 2 and the pads 72 by dispersing stress in particular directions. Further, the terminals 2 in the semiconductor device B2 are concentrated closer to the center than in the semiconductor device B1. Thus, the semiconductor device B2 is advantageous for reducing the dimension in the second direction y.

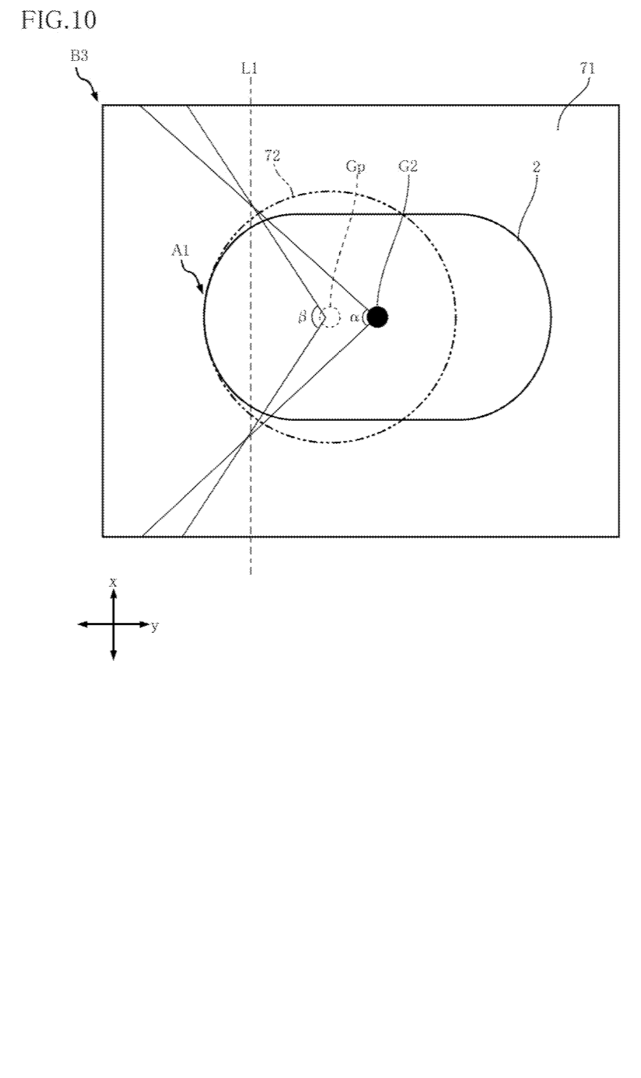

FIG. 10 shows a semiconductor device B3 according to a variation of the second embodiment. In the semiconductor device B3, the center of gravity G2 of the terminal 2 does not coincide with the center of gravity Gp of the pad 72, as viewed in the third direction z. More specifically, the center of gravity G2 of the terminal 2 is offset farther (to the right side in FIG. 10) from the line segment L1 than the center of gravity Gp of the pad 72. The pad 72 in the present variation overlaps with the line segment L1, and is divided into two regions by the line segment L1.

FIG. 10 shows the angle α and the angle β. The angle α corresponds to the angle formed by the line segments connecting the centers of gravity of three terminals 2. The angle β corresponds to the angle formed by the line segments connecting the centers of gravity of three pads 72. The distance between an adjacent pair among the three terminals 2 is larger than the distance between an adjacent pair among the three pads 72. Thus, the angle α is smaller than the angle β.

As with the semiconductor device B2, the semiconductor device B3 has an advantage of reducing the risk of damaging the terminals 2 and the pads 72 by dispersing stress in particular directions.

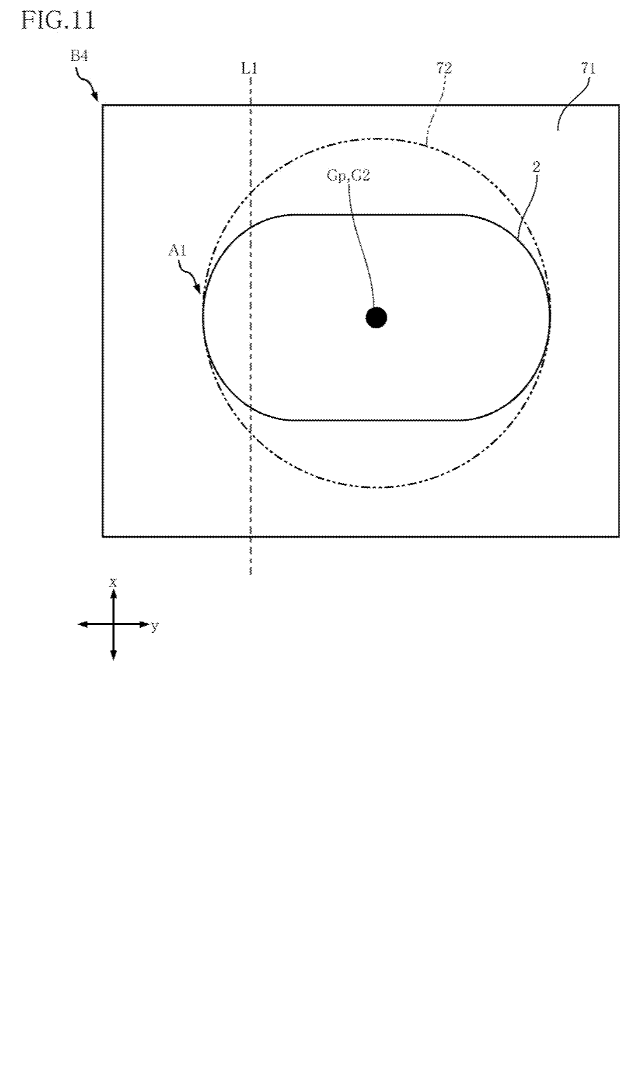

FIG. 11 shows a semiconductor device B4 according to a variation of the second embodiment. In the semiconductor device B4, the pad 72 surrounds the periphery of the terminal 2, as viewed in the third direction z. The dimension of the pad 72 in the second direction y may be equal to or larger than the dimension of the terminal 2 in the second direction y. In the illustrated example, the center of gravity G2 of the terminal 2 overlaps with the center of gravity Gp of the pad 72, as viewed in the third direction z. Alternatively, the center of gravity G2 of the terminal 2 may be offset from the center of gravity Gp of the pad 72.

According to such a configuration, the conductive connecting member 50 in a molten state is less likely to extend outward beyond the periphery of the pad 72. Thus, the semiconductor device B4 is advantageous for improving the bonding stability.

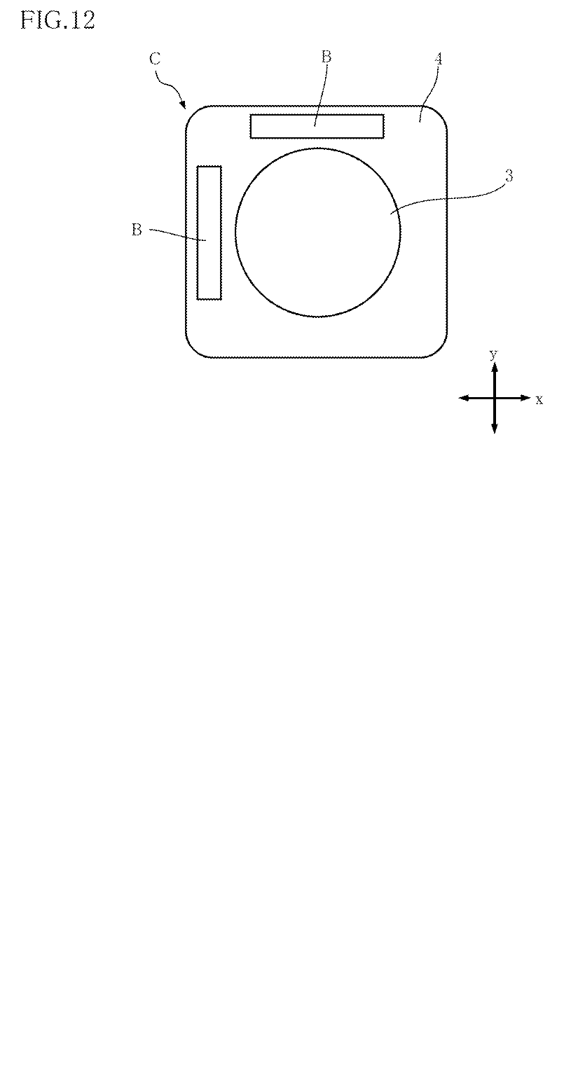

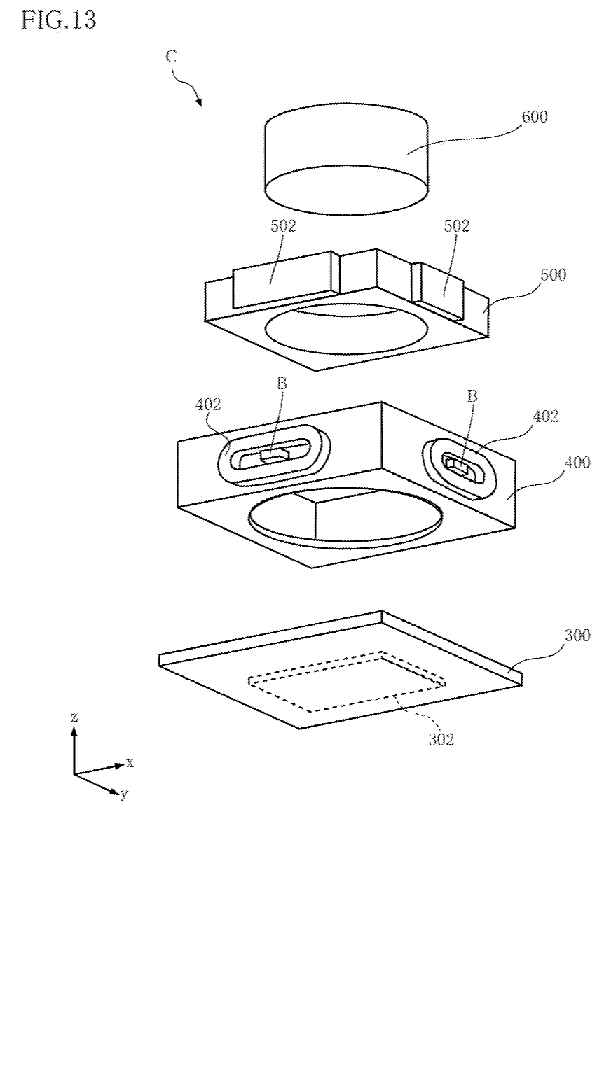

The semiconductor devices B1 to B4 (hereinafter "semiconductor devices B") according to the second embodiment of the present disclosure are mountable onto a camera module C, for example. Each of FIGS. 12 and 13 shows the camera module C provided with semiconductor devices B. FIG. 13 shows an exploded perspective view showing the camera module C according to the present embodiment. The camera module C includes a lens 3 for a camera, semiconductor devices B, which are each provided with a position detection sensor 4 for detecting the position of the lens 3, etc., and other elements such as coils and magnets (not illustrated) for adjusting the position of the lens 3. This makes it possible to provide the function of lens position control for adjusting the position of the lens 3. The lens position control includes an autofocus mechanism and an image stabilization mechanism.

The components of the camera module C may be arranged around the lens 3. In other words, the semiconductor devices B may be arranged around the lens position control mechanisms, such as the autofocus mechanism and the image stabilization mechanism, for controlling the position of the lens 3. The position detection sensors 4 may be provided in the respective semiconductor devices B. Each of the semiconductor devices B may be housed in a unit, or may be arranged outside a member for supporting the lens 3. Each of the semiconductor devices B is not limited to one provided with a position detection sensor 4, and may be provided with other electronic components.

FIG. 13 shows an exploded perspective view showing the camera module C according to the present embodiment. The camera module C includes a substrate 300, a base 400, a holding frame 500, and a lens unit 600. The substrate 300 has an imaging element 302 arranged thereon. The imaging element 302 may be configured with a charge-coupled device (CCD) or a complementary metal-oxide-semiconductor (CMOS). The imaging element 302 outputs image data of an optical image formed via the lens unit 600.

The holding frame 500 holds the lens unit 600 inside. The outer surfaces of the holding frame 500 are provided with magnets 502. The base 400 holds the holding frame 500 and the lens unit 600 such that they can move in the direction of the optical axis of the lens unit 600 (Z-axis direction) and in directions (X-axis and Y-axis directions) intersecting the optical axis. Side surfaces of the base 400 are each provided with a coil 402 and a semiconductor device B. The coils 402 are positioned to face the magnets 502. The coils 402 may be air-core coils. The magnets 502 and the coils 402 function as a voice coil motor (VCM), which is a drive source for moving or rotating the holding frame 500 relative to the base 400.

When a current flows through each coil 402 within the magnetic field of the corresponding magnet 502, a force is generated on the coil 402 in a direction perpendicular to the magnetic field. This applies thrust to the holding frame 500 along the first direction x or the second direction y. It is possible to design the arrangement of the coils 402 or the orientation of the magnetic field of each magnet 502 such that applying a current to the coils 402 imparts thrust to the holding frame 500 along the Z direction.

Each of the semiconductor devices B is arranged in the air-core of a coil 402. The semiconductor device B may function as a position sensor for detecting the position or posture of the holding frame 500 relative to the base 400. The position sensor may be a magnetic sensor including a Hall element. The position sensor may output a voltage whose magnitude corresponds to a change in magnetic field. Movement of the holding frame 500 changes the positional relationship between the semiconductor device B and the magnet 502, and the magnitude of the magnetic field detected at the position changes accordingly. As such, the position sensor detects the position of the magnet 502 relative to the semiconductor device B, in other words, the position of the holding frame 500 relative to the base 400. The magnetic sensor may include an electromagnetic conversion element other than a Hall element. The magnetic sensor may be one of various sensors for detecting a magnetic field, such as a spin-valve magnetoresistive element (e.g., a GMR element or a TMR element) whose resistance varies in response to a change in an external magnetic field, or may be a combination of such sensors. Alternatively, the magnetic sensor may be composed of a group of a plurality of magnetic sensor elements.

Each of the semiconductor devices B supplies current to a corresponding coil 402 in order to adjust the position or posture of the holding frame 500 to a target position or posture, based on the position or posture of the holding frame 500 relative to the base 400. The semiconductor devices B may be provided outside the respective coils 402. The holding frame 500 may include the semiconductor devices B and the coils 402, and the base 400 may include the magnets 502.

Incorporating the semiconductor devices B of the present application into the camera module C can downsize the camera module C. This is because the semiconductor devices B (the semiconductor elements A1 to A4) arranged around the lens 3 are made smaller.

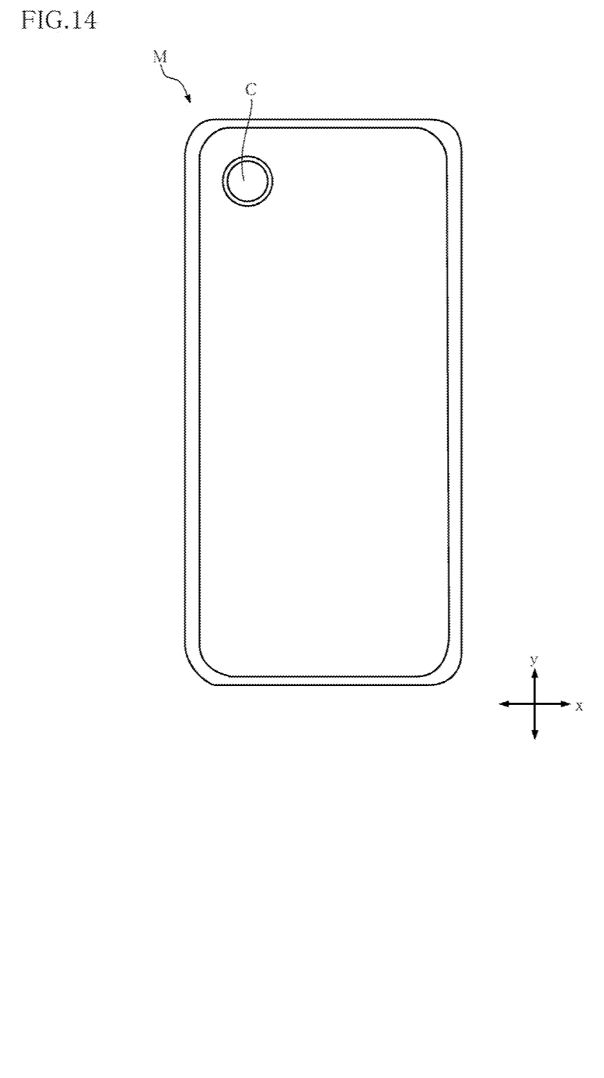

The camera module C in the present disclosure may be used in a mobile terminal M equipped with a camera. FIG. 14 shows a schematic rear view showing the mobile terminal M equipped with the camera module C. The mobile terminal M includes the camera module C that functions as, for example, a rear camera. The camera module C includes an autofocus mechanism and an image stabilization function. Thus, the mobile terminal M can automatically adjust focus when capturing an image of a subject and optically correct shake (vibration) generated during shooting, thereby capturing an image with reduced blur.

The camera module C of the present disclosure is not limited to the camera for the mobile terminal M, and may be used for other applications. For example, the camera module C may be used for a camera-equipped device that includes an in-vehicle camera module VC (Vehicle Camera). The in-vehicle camera module VC may be attached to a windshield, facing forward, or to a rear gate, facing rearward. The in-vehicle camera module VC functions as a rear-view camera, a drive recorder, a collision-avoidance control camera, or an autonomous-driving control camera.

The semiconductor element and the semiconductor device according to the present disclosure are not limited to the above embodiments. The technical concept of the present disclosure does not specify the materials, shapes, structures, arrangements, etc., of the components. The technical concept of the present disclosure can be modified in various ways within the technical scope defined by the claims.

The semiconductor device according to the present disclosure encompasses the embodiments described in the following clauses.

Clause 1.

A semiconductor element (A1) comprising a plurality of terminals (2),

wherein the semiconductor element (A1) includes a line segment (L1) that overlaps with the plurality of terminals (2),

the plurality of terminals (2) are arranged along a first direction (x) of the semiconductor element (A1),

the plurality of terminals (2) include a first group (21), in which centers of gravity (G1) are offset to a first side in a second direction (y) perpendicular to the first direction (x), and a second group (22), in which centers of gravity (G2) are offset to an opposite side from the first group (21) with respect to the line segment (L1), and

each of the plurality of terminals (2) has a shape in which a dimension (S2) in the second direction (y) is larger than a dimension (S1) in the first direction (x).

Clause 2.

The semiconductor element (A1) according to clause 1, wherein the centers of gravity (G1) of the terminals (2a to 2c) in the first group (21) coincide with each other in the second direction (y), and

the centers of gravity (G2) of the terminals (2d to 2f) in the second group (22) coincide with each other in the second direction (y).

Clause 3.

The semiconductor element (A1) according to clause 1 or 2, wherein adjacent two terminals (2) out of the plurality of terminals (2) include long axes that are parallel to each other.

Clause 4.

The semiconductor element (A1) according to any one of clauses 1 to 3, wherein the terminals (2a to 2c) in the first group (21) are arranged alternately with the terminals (2d to 2f) in the second group (22).

Clause 5.

The semiconductor element (A2) according to any one of clauses 1 to 4, wherein at least one of the plurality of terminals (2) has a teardrop shape including a portion tapered toward the line segment (L1).

Clause 6.

The semiconductor element (A1) according to any one of clauses 1 to 5, wherein each of the plurality of terminals (2) includes a first region (R1), in which a center of gravity (G1, G2) is located, and a second region (R2), in which a center of gravity (G1, G2) is not located, with respect to the line segment (L1), and a ratio of the first region (R1) to the second region (R2) is at most 98%.

Clause 7.

The semiconductor element (A3) according to any one of clauses 1 to 6, wherein at least one of the plurality of terminals (2) has an elliptical shape.

Clause 8.

The semiconductor element (A4) according to any one of clauses 1 to 6, wherein at least one of the plurality of terminals (2) has a polygonal shape.

Clause 9.

The semiconductor element (A1) according to any one of clauses 1 to 8, wherein the semiconductor element is provided in a wafer-level chip scale package (WL-CSP).

Clause A1.

The semiconductor element (A1) according to any one of clauses 1 to 9, comprising:

a body (11) that includes a semiconductor layer (112);

an electrode (12) that is located on a first side in a third direction (z) relative to the body (11) and electrically connected to the semiconductor layer (112);

a first contact layer (421) and a second contact layer (422) electrically connected to the electrode (12); and

a conductive connecting member (50) that is located on a side opposite to the electrode (12) with respect to the first contact layer (421) in the third direction (z), and that is electrically connected to the first contact layer (421) and the second contact layer (422),

wherein the first contact layer (421) and the second contact layer (422) are spaced apart from each other in a direction perpendicular to the third direction (z), and

as viewed in the third direction (z), the conductive connecting member (50) overlaps with the first contact layer (421) and the second contact layer (422).

Clause A2.

The semiconductor element (A1) according to clause A1, wherein one of the plurality of terminals (2) is electrically connected to the conductive connecting member (50),

the conductive connecting member (50) is located on a side opposite to a rewiring layer (41) with respect to the corresponding terminal (2), and

a melting point of the conductive connecting member (50) is lower than a melting point of the terminal (2).

Clause A3.

The semiconductor element (A1) according to clause A1 or A2, wherein as viewed in the third direction (z), an area of each of the first contact layer (421) and the second contact layer (422) is smaller than an area of the conductive connecting member (50).

Clause A4.

The semiconductor element (A1) according to clause A3, wherein as viewed in the third direction (z), the terminal (2) overlaps with an entirety of each of the first contact layer (421) and the second contact layer (422).

Clause A5.

The semiconductor element (A1) according to any one of clauses A1 to A4, wherein the first contact layer (421) and the second contact layer (422) are electrically connected to the electrode (12).

Clause A6.

The semiconductor element (A1) according to any one of clauses A1 to A5, further comprising a first protective film (30) located on a same side as the electrode (12) with respect to the body (11) and covering a part of the electrode (12) and the body (11),

wherein the first protective film (30) includes a first opening (30a) that passes through the first protective film (30) in the third direction (z), and that exposes the electrode (12), and

at least a part of each of the first contact layer (421) and the second contact layer (422) is accommodated in the first opening (30a).

Clause A7.

The semiconductor element (A1) according to clause A6, wherein the first protective film (30) contains one of silicon dioxide and silicon nitride.

Clause A8.

The semiconductor element (A1) according to clause A6 or A7, further comprising:

a second protective film (31) that covers the first protective film (30); and

a rewiring layer (41) located between the first contact layer (421) and the conductive connecting member (50) in the third direction (z),

wherein the rewiring layer (41) is electrically connected to the first contact layer (421), the second contact layer (422), and the conductive connecting member (50), and

the second protective film (31) includes a portion located between the first protective film (30) and the rewiring layer (41).

Clause A9.

The semiconductor element (A1) according to clause A8, further comprising a third protective film (32) that covers the second protective film (31) and the rewiring layer (41),

wherein the third protective film (32) is in contact with the plurality of terminals (2), and the conductive connecting member (50) is exposed from the third protective film (32).

Clause 10.

A semiconductor device (B1) comprising: the semiconductor element (A1) according to any one of clauses 1 to 9 and A1 to A9; and an external substrate (7) electrically connected to the semiconductor element (A1),

wherein the external substrate (7) includes a plurality of pads (72) electrically connected to the plurality of terminals (2), respectively, and

each of the plurality of pads (72) has a shape different from a shape of each of the plurality of terminals (2).

Clause 11.

The semiconductor device (B1) according to clause 10, wherein a distance (D2) between an adjacent pair of the plurality of terminals (2) in the first direction (x) is greater than a distance (D5) between an adjacent pair of the plurality of pads (72) in the first direction (x).

Clause 12.

The semiconductor device (B1) according to clause 10 or 11, wherein the dimension (S1) of each of the plurality of terminals (2) in the first direction (x) is smaller than a dimension (S3) of each of the plurality of pads (72) in the first direction (x).

Clause 13.

The semiconductor device (B1) according to any one of clauses 10 to 12, wherein each of the plurality of pads (72) has a circular shape.

Clause 14.

The semiconductor device (B1) according to any one of clauses 10 to 13, wherein the plurality of terminals (2) include six terminals (2a to 2f), and

the plurality of pads (72) include six pads (72a to 72f).

Clause 15.

The semiconductor device (B1) according to any one of clauses 10 to 14, wherein the center of gravity (G1, G2) of each of the plurality of terminals (2) overlaps with a center of gravity (Gp) of a corresponding one of the plurality of pads (72).

Clause 16.

The semiconductor device (B2, B3) according to any one of clauses 10 to 14, wherein the center of gravity (G1, G2) of each of the plurality of terminals (2) is offset from a center of gravity (Gp) of a corresponding one of the plurality of pads (72).

Clause 17.

The semiconductor device (B4) according to any one of clauses 10 to 15, wherein each of the plurality of pads (72) surrounds a periphery of each of the plurality of terminals (2).

Clause 18.

The semiconductor device (B1–B4) according to any one of clauses 10 to 17, further comprising a plurality of conductive connecting members (50),

wherein the plurality of conductive connecting members (50) are located between the plurality of terminals (2) and the plurality of pads (72) in the third direction (z).

Clause 19.

A camera module (C) comprising the semiconductor device (B) according to any one of clauses 10 to 18.

Clause 20.

A mobile terminal (M) comprising the camera module (C) according to clause 19.

1. A semiconductor element comprising a plurality of terminals,
wherein the semiconductor element includes a line segment that overlaps with the plurality of terminals,
the plurality of terminals are arranged along a first direction of the semiconductor element,
the plurality of terminals include a first group, in which centers of gravity are offset to a first side in a second direction perpendicular to the first direction, and a second group, in which centers of gravity are offset to an opposite side from the first group with respect to the line segment, and
each of the plurality of terminals has a shape in which a dimension in the second direction is larger than a dimension in the first direction.

2. The semiconductor element according to claim 1, wherein the centers of gravity of the terminals in the first group coincide with each other in the second direction, and
the centers of gravity of the terminals in the second group coincide with each other in the second direction.

3. The semiconductor element according to claim 1, wherein adjacent two terminals out of the plurality of terminals include long axes that are parallel to each other.

4. The semiconductor element according to claim 1, wherein the terminals in the first group are arranged alternately with the terminals in the second group.

5. The semiconductor element according to claim 1, wherein at least one of the plurality of terminals has a teardrop shape including a portion tapered toward the line segment.

6. The semiconductor element according to claim 1, wherein each of the plurality of terminals includes a first region, in which a center of gravity is located, and a second region, in which a center of gravity is not located, with respect to the line segment, and
a ratio of the first region to the second region is at most 98%.

7. A semiconductor device comprising: the semiconductor element according to claim 1; and an external substrate electrically connected to the semiconductor element,
wherein the external substrate includes a plurality of pads electrically connected to the plurality of terminals, respectively, and
each of the plurality of pads has a shape different from a shape of each of the plurality of terminals.

8. The semiconductor device according to claim 7, wherein a distance between an adjacent pair of the plurality of terminals in the first direction is greater than a distance between an adjacent pair of the plurality of pads in the first direction.

9. The semiconductor device according to claim 7, wherein the dimension of each of the plurality of terminals in the first direction is smaller than a dimension of each of the plurality of pads in the first direction.

10. The semiconductor device according to claim 7, wherein each of the plurality of pads has a circular shape.

11. The semiconductor device according to claim 7, wherein the center of gravity of each of the plurality of terminals overlaps with a center of gravity of a corresponding one of the plurality of pads.

12. The semiconductor device according to claim 7, wherein the center of gravity of each of the plurality of terminals is offset from a center of gravity of a corresponding one of the plurality of pads.

13. The semiconductor device according to claim 7, wherein each of the plurality of pads surrounds a periphery of each of the plurality of terminals.

14. A camera module comprising the semiconductor device according to claim 8.
